(19) United States
(12) Patent Application Publication
(10) Pub. No.: US 2023/0369267 A1
(43) Pub. Date: Nov. 16, 2023

(54) 3D Packaging Heterogeneous Area Array Interconnections

(71) Applicant: Avago Technologies International Sales Pte. Limited, Singapore (SG)

(72) Inventors: Sam Zhao, Irvine, CA (US); Mayank Mayukh, Fort Collins, CO (US); Sam Karikalan, Ladera Ranch, CA (US); Reza Sharifi, Irvine, CA (US); Arun Ramakrishnan, Lake Forest, CA (US); Liming Tsau, Irvine, CA (US); Dharmendra Saraswat, Foothill Ranch, CA (US)

(21) Appl. No.: 17/741,621

(22) Filed: May 11, 2022

(51) Int. Cl. H01L 23/00

(52) U.S. Cl. CPC H01L 24/13; H01L 24/97; H01L 24/03; H01L 24/05; H01L 24/11; H01L 2224/05147; H01L 2224/1412; H01L 2224/0612; H01L 2224/97

(57) ABSTRACT

An apparatus includes an interposer comprising one or more area array interconnections, the one or more area array interconnections including a first type of area array interconnection and a second type of area array interconnection. The apparatus further includes a first die coupled to the interposer via the first type of area array interconnection, and a second die coupled to the interposer via the second type of area array interconnection, wherein the first type of area array interconnection is different from the second type of area array interconnection.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for a semiconductor package including a three-dimensional (3D) area array packaging utilizing heterogeneous interconnections.

### BACKGROUND

Conventionally, flip chip and wire bonding are common interconnect methods for active silicon interconnection with an organic chip carrier, such as a substrate or interposer. In a chiplet package, different chips may utilize different die-to-carrier interconnection depending on desired functional characteristics and manufacturing costs. For example, flip chip bonding and wire bonding interconnection methods are used to connect flip chip die and wire bond die to the same substrate. For heterogeneous integration of various chips in a package, homogeneous area array interconnection using flip chip technology has also been used to enable chiplet interconnection on the same organic chip carrier.

For next generation chiplets that include chips both with and without area array bumps on their input/output (I/O) terminals (e.g., pads), a heterogeneous area array interconnection of chiplets is provided. Thus, methods, systems, and apparatuses for a mixed 3D packaging area array are provided.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1 is a schematic cross-sectional view of a semiconductor package with heterogeneous area array interconnections, in accordance with various embodiments;

FIG. 2 is a schematic cross-sectional view of an alternative arrangement of a semiconductor package with heterogeneous area array interconnections, in accordance with various embodiments;

FIG. 3 is a schematic cross-sectional view of a chiplet package with heterogeneous area array interconnections utilizing a silicon stiffener and heat spreader plane, in accordance with various embodiments;

FIG. 4 is a schematic cross-sectional view of a chiplet package with heterogeneous area array interconnections utilizing silicon oxide (SiOx) bonding and gap filling, in accordance with various embodiments;

FIG. 5 is a flow diagram of a method of manufacturing a chiplet package with heterogeneous area array interconnections, in accordance with various embodiments.

### DETAILED DESCRIPTION OF EMBODIMENTS

Various embodiments set forth a chiplet package with heterogeneous area array interconnections, and methods of manufacturing a chiplet package with heterogeneous area array interconnections.

In some embodiments, an apparatus for a semiconductor package with heterogeneous area array interconnections is provided. The apparatus includes an interposer that includes one or more area array interconnections, the one or more area array interconnections including a first type of area array interconnection and a second type of area array interconnection. A first die is coupled to the interposer via the first type of area array interconnection, and a second die is coupled to the interposer via the second type of area array interconnection. The first type of area array interconnection is different from the second type of area array interconnection.

In further embodiments, a semiconductor device with heterogeneous area array interconnections is provided. The semiconductor device includes a circuit board comprising one or more internal layers, and a first semiconductor package coupled to the circuit board. The first semiconductor package includes a substrate coupled to the circuit board, an interposer coupled to the circuit board, the interposer comprising one or more area array interconnections, the one or more area array interconnections including a first type of area array interconnection and a second type of area array interconnection, a first die coupled to the interposer via the first type of area array interconnection, and a second die coupled to the interposer via the second type of area array interconnection. The first type of area array interconnection is different from the second type of area array interconnection. The semiconductor device includes a second semiconductor package coupled to the circuit board, the second semiconductor package further coupled to the first semiconductor package via at least one of the one or more internal layers of the circuit board.

In further embodiments, a method of manufacturing a chiplet package with heterogeneous area array interconnections is provided. The method includes forming an interposer comprising one or more area array interconnections, the one or more area array interconnections including a first type of area array interconnection and a second type of area array interconnection, connecting a first die to the interposer via the first type of area array interconnection, and connecting a second die to the interposer via the second type of area array interconnection, wherein the first type of area array interconnection is different from the second type of area array interconnection. The method further includes bonding the interposer to a package substrate.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Similarly, when an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

In conventional semiconductor packages, interconnects utilizing a homogeneous area array are limited in both the types of chips capable of being interconnected, as well as performance achievable utilizing traditional wire bonding or flip chip bonding. For example, for packages utilizing a homogeneous area array interconnection, chips and chiplet packages are limited to those with area array bumps (e.g., solder bumps/balls). Moreover, bump pitch is physically limited so as to ensure appropriate bonding and interconnection. As used herein, pitch may refer to the spacing between bumps, copper posts, pads, or other electrical connections. Furthermore, traditional approaches to multi-die packaging have been to utilize Si interposers with through silicon vias (TSVs). However, due to the parasitic effects in Si, performance and bandwidth are limited. Thus, utilizing traditional microbump (uBump) silicon (Si) interposers present challenges with signal integrity and warpage.

The proposed heterogeneous (e.g., mixed) area array interconnection allows for better signal integrity and warpage control by utilizing an organic interposer layer over a traditional Si interposer layer. Furthermore, area arrays interconnection utilizing hybrid or direct copper (Cu) bonding allows for finer bump pitch (e.g., −10 micron), which in turn allows higher bandwidth and lower latency connections between dies and memory.

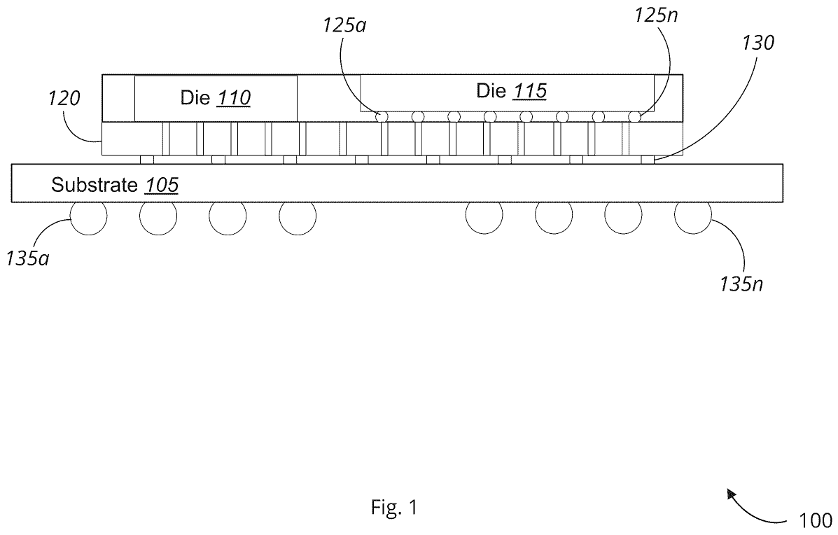

FIG. 1 is a schematic cross-sectional view of a semiconductor package 100 with heterogeneous area array interconnections, in accordance with various embodiments. The semiconductor package 100 includes a substrate 105, first die 110, second die 115, interposer 120, a first plurality of solder bumps 125a-125n, a second plurality of solder bumps 130, and third plurality of solder bumps 135a-135n. It should be noted that the various components of semiconductor package 100 are schematically illustrated in FIG. 1, and that modifications to the various components and other arrangements of semiconductor package 100 may be possible and in accordance with the various embodiments.

In various embodiments, the semiconductor package 100 includes a substrate 105. The substrate 105 may provide one or more surfaces for die placement. In some examples, the substrate 105 may include one or more respective routing layers used for component interconnects. In some examples, the substrate 105 may be a redistribution layer (RDL) and/or printed circuit board (PCB) substrate. In some examples, the substrate 105 may include two or more internal layers (e.g., routing layers). Routing layers may include any layer configured to provide component interconnects. For example, routing layers are layers of the substrate through which interconnections may be established between components. Connections may be routed, for example, through copper pads, copper/metal traces deposited on/in the substrate layer, and through-hole vias, or other suitable interconnects.

In various examples, the first die 110 and second die 115 may be coupled to the substrate 105 via an interposer 120. Specifically, the interposer 120 may couple the first and second dies 110, 115 having respective pitch connections (e.g., electrical connections of a respective pitch) to a larger pitch connection of the substrate 105. In some examples, first die 110 may have connections of a first pitch, and second die 115 may have connections of a second pitch. The first and second pitches may be finer pitch connections than the connections of the substrate 105.

In some examples, the interposer 120 may itself be a substrate for one or more dies, such as first die 110 and second die 115. In some examples, the interposer 120 may be an organic interposer. Organic interposers may include interposers formed of organic and/or polymer compounds. Organic small molecules may include, without limitation, polycyclic aromatic compounds such as pentacene, anthracene, rubrene, etc., as known to those skilled in the art. In yet further examples, the interposer 120 may include glass, silicon, an organic compound, or a combination of glass, silicon, and/or an organic compound.

In some examples, the interposer 120 may be coupled to the substrate 105 via a second plurality of solder bumps 130. In further examples, the interposer 120 may be coupled to the substrate 105 via Cu post (CuP) bonding, or a solder cap on the Cu post contact tip. In various examples, the interposer 120 may further include a heterogeneous area array for coupling of dies, such as first die 110 and second die 115, to the interposer 120. In various embodiments, the heterogeneous area array may include an area array for electrical interconnections, such as copper pads, CuPs, and/or TSVs. More specifically, a heterogeneous area array includes two or more arrays of different types of interconnections (e.g., a solder-bonded interconnection via copper pads and/or copper pillars with solder tips, or a copper-bonded interconnection, as described in greater detail below). Each array of interconnections may include connections that are both physical and electrical, arranged in a respective region (e.g., area) of the interposer. In some examples, an area array may be arranged in a pattern, such as, without limitation, a rectangular grid. Accordingly, in some examples, the area array may provide an interface configured to allow a flip-chip die or other component to be coupled to the interposer 120.

In some embodiments, the heterogeneous area array may include two or more area array interconnections that are added to the interposer 120. In some examples, each area array interconnection may include an intervening material or layer, such as, without limitation, one or more metallization layers.

In some examples, the heterogeneous area array includes electrical connections for two or more types of die connections. For example, in various embodiments, the first die 110 may be copper-bonded (Cu—Cu bonding), for example, via hybrid copper bonding (HCB) and/or direct copper bonding (DCB), to the interposer 120, whereas the second die 115 may be coupled to the interposer 120 via a plurality of solder bumps 125a-125n (e.g., uBumps, Cu bumps, etc.). Specifically, the DCB and/or HCB may include copper-to-copper bonding via a wafer bonding process.

In various embodiments, the substrate 105 may further include a third plurality of solder bumps 135a-135n. The substrate 105 may, for example, be configured to couple the semiconductor package 100 to another substrate and/or circuit board.

In various examples, the first die 110 and/or second die 115 may include semiconductor dies, such as flip chip dies. Thus, the first die 110 and/or second die 115 may, in some examples, be surface mounted or wire bonded. In some examples, the first die 110 and second die 115 may be surface mounted to a surface of the interposer 120. Alternatively, in some examples, the first die 110 and/or second die 115 may be coupled to an internal layer of the interposer 120 (e.g., where the interposer 120 is itself a substrate including two or more layers). In some examples, the first die 110 and/or second die 115 may include active die. In further examples, the interposer 120 may further be coupled to one or more passive components. Passive components may include, for example, filters and other components (e.g., resistive, capacitive, and/or inductive elements).

In some examples, the first die 110 and/or second die 115 may further be encapsulated with epoxy molding compounds (EMCs). Molding may be introduced, and a top layer of the dies (and corresponding molding) may be grinded during a grinding process, to a given height and/or thickness. After grinding, the die molding may be selectively removed, for example, using a stop layer. Thus, die molding may be used to mechanically reinforce the dies attached to interposer 120.

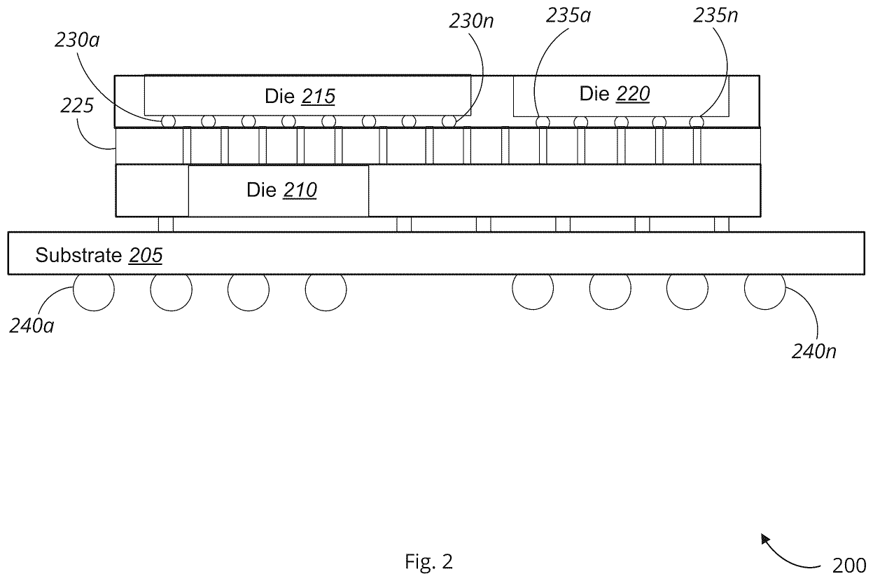

Different arrangements of semiconductor packages are illustrated below with respect to FIGS. 2-4.

FIG. 2 is a schematic cross-sectional view of an alternative arrangement of a semiconductor package 200 with heterogeneous area array interconnections, in accordance with various embodiments. The semiconductor package 200 includes a substrate 205, first die 210, second die 215, third die 220, interposer 225, a first plurality of solder bumps 230a-230n, a second plurality of solder bumps 235a-235n, and third plurality of solder bumps 240a-240n. It should be noted that the various components of semiconductor package 200 are schematically illustrated in FIG. 2, and that modifications to the various components and other arrangements of semiconductor package 200 may be possible and in accordance with the various embodiments.

In the embodiments depicted, the interposer 225 may be coupled to dies on both a first side (e.g., a first surface) and a second side (e.g., a second surface) opposite the first side of the interposer 225. For example, in some embodiments, the interposer 225 may be coupled, on a bottom side (e.g., a first side) to a first die 210, and on a top side (e.g., a second side) to a second die 215 and third die 220.

In some examples, the top side of the interposer 225 may include an area array configured to couple to the second die 215 and third die 220 via solder bumps. For example, the second die 215 may is coupled to the interposer 225 via a first plurality of solder bumps 230a. The third die 220 is coupled to the interposer 225 via a second plurality of solder bumps 235a-235n.

The bottom side of the interposer 225 may include an area array configured to couple to the first die 210 via Cu—Cu bonding. Accordingly, in some examples, the heterogeneous area array may include different types of area arrays on different sides of the interposer 225. In various examples, each of the first die 210, second die 215, and third die 220 may include respective connection pitch (e.g., space between electrical connections).

In some examples, the first die 210 may further be coupled to the substrate 205 via traditional bonding techniques (e.g., flip-chip bonding). Like the substrate 105 of FIG. 1, substrate 205 may further include a third plurality of solder bumps 240a-240n configured to couple the semiconductor package 200 to other components or other parts of a larger system. For example, substrate 205 may be coupled to another substrate or circuit board.

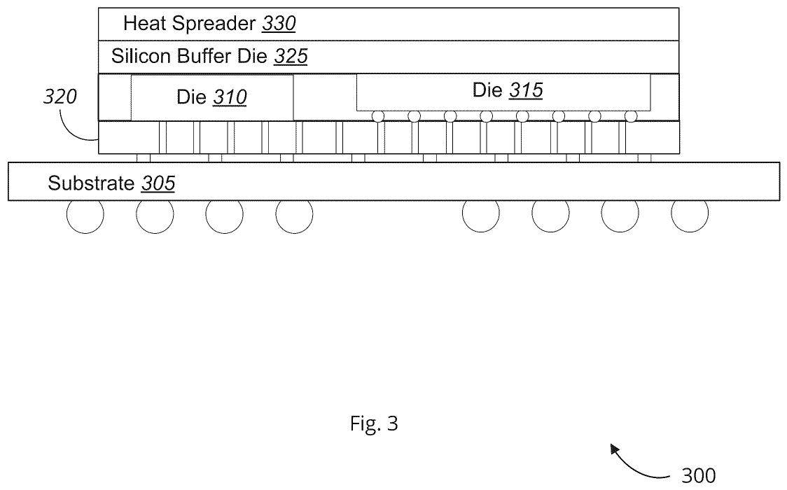

FIG. 3 is a schematic cross-sectional view of a chiplet package 300 with heterogeneous area array interconnections utilizing a silicon stiffener/silicon buffer die and heat spreader plane, in accordance with various embodiments. The semiconductor package 300 includes a substrate 305, first die 310, second die 315, interposer 320, a silicon buffer die 325, and heat spreader plane 330. It should be noted that the various components of semiconductor package 300 are schematically illustrated in FIG. 3, and that modifications to the various components and other arrangements of semiconductor package 300 may be possible and in accordance with the various embodiments.

In the embodiment depicted, as in FIG. 1, the interposer 320 is coupled to a first die 310 via copper bonding (HCB and/or DCB) and to the second die 315 via a plurality of solder bumps. Thus, the interposer 320 may include a heterogeneous area array supporting connections to the first and second dies 310, 315 via different interconnections (e.g., copper bonding and solder bumps, respectively). In various examples, the semiconductor package 300 further includes a silicon buffer die 325 and heat spreader plane 330.

Silicon buffer die 325 may include, for example, one or more of a silicon carrier die, buffer die, or other silicon wafer substrate. The silicon buffer die 325 may be configured to provide additional rigidity and/or mechanical strength to the first and second dies 310, 315, interposer 320, and/or substrate 305. In some examples, the silicon buffer die 325 may further be configured to be a transition layer to promote thermal contact between the first and second die 310, 315 and the heat spreader plane 330.

In some examples, the silicon buffer die 325 may be a silicon die and/or a silicon-oxide (SiO₂) die. In further examples, the silicon buffer die 325 may alternatively be a buffer layer formed of other materials. The buffer layer, for example, may include, without limitation, tantalum nitride (TaN), nickel (Ni), ruthenium (Ru), cobalt (Co), tungsten (W), aluminum nickel (AlNi), or other suitable material. In some examples, the heat spreader plane 330 includes a multi-layer graphene (MLG) heat spreader plane. In further examples, the heat spreader plane 330 may include a thermally conductive coating/film and/or a metal vapor chamber. Accordingly, in various embodiments, the heat spreader plane 330 may be configured to distribute heat from localized hot spots (e.g., over certain die) more evenly over the semiconductor package 300. In some examples, the silicon buffer die 325 is bonded to the tops of the first and second die 310, 315. In some examples, the silicon buffer die 325 may be coupled to EMC (e.g., molding) of the first and second die 310, 315. The MLG (e.g., heat spreader plane 330) may then be deposited or otherwise bonded to the silicon buffer die 325.

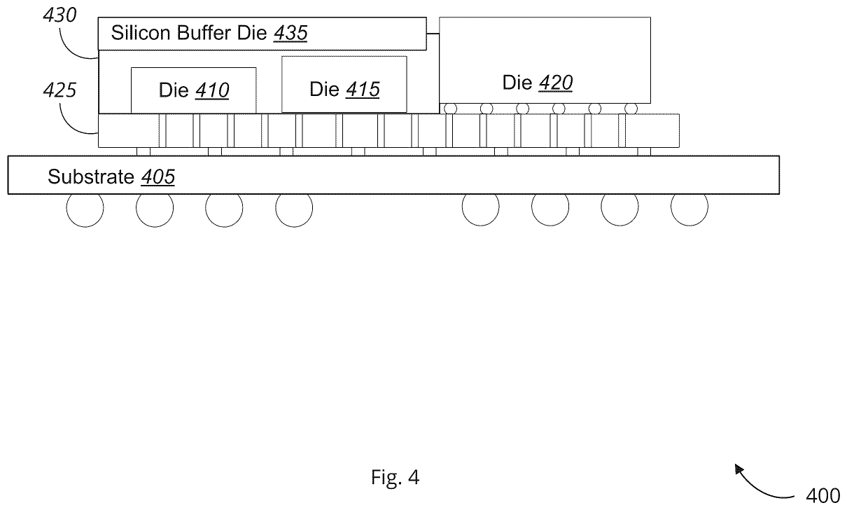

FIG. 4 is a schematic cross-sectional view of a chiplet package with heterogeneous area array interconnections utilizing silicon oxide (SiOx) bonding and gap filling, in accordance with various embodiments; The semiconductor package 400 includes a substrate 405, first die 410, second die 415, Third die 420, interposer 425, SiOx filler 430, and silicon buffer die 435. It should be noted that the various components of semiconductor package 100 are schematically illustrated in FIG. 1, and that modifications to the various components and other arrangements of semiconductor package 100 may be possible and in accordance with the various embodiments.

In various examples, the interposer 425 may be coupled to first die 410, second die 415, and third die 420. The first and second dies 410, 415 may be coupled to the interposer 425 via Cu—Cu bonding. Third die 420 may similarly be coupled to the interposer 425 via solder uBumps or Cu pillars with solder cap.

Dies such as third die 420 may include a stack of DRAM die (e.g., a high-bandwidth memory (HBM) die) that are mounted to the interposer 425, and can be thicker than Cu—Cu bonded dies (first die 410 and second die 415). To make up differences in thickness with larger dies that may not be Cu—Cu bonded to the interposer 425, various techniques may be utilized.

Because the height of the third die 420 can be greater than the height of the first die and second die 415, in some examples, a gap may be present between the first and second dies 410, 415, and the third die 420. Furthermore, a gap may also exist between the first and second dies 410, 415. Thus, according to various examples, the gap may be filled with a SiOx filler 430, and further, a silicon buffer die 435 may be used in combination with the SiOx filler 430 to match the height (e.g., thickness) of the first and second dies 410, 415, as well as to the height of the third die 420.

In some examples, using overmolding (e.g., via an EMC) may cause mismatches in coefficient of thermal expansions (CTE) between the Si-molding interface (e.g., die material may be silicon whereas EMC is a polymer compound), which further leads to warpage and package yield reliability issues. Thus, in some examples, silicon buffer die 435 may be coupled to the first die 410 and second die 415 via SiOx filler 430. CTE mismatch is reduced by use of SiOx filler 430, as the CTE of the SiOx and the CTE of Si dies (e.g., the first and second dies 410, 415) are closer than between EMC and Si dies. In some examples, SiOx-SiOx bonding may be used to bond the silicon buffer die 435 to the first and second dies 410, 415. In various examples, SiOx filler 430 may include various types of SiOx, such as, without limitation, SiOx, silicon oxynitride (SiOxNy), and silicon carbon nitride (SiCxNy).

Accordingly, in various embodiments, the SiOx filler 430 acts as an interface and bonding material between the silicon buffer die 435 and active dies, such as each of the first and second dies 410, 415, as well as a bonding material between active dies, such as first and second dies 410, 415. In further examples, the SiOx filler 430 may interface with microbump underfill between the dies, such as first and second dies 410, 415, and for example, an HBM, such as third die 420. In some further examples, SiOx filler 430 may be deposited and subsequently backgrinded to appropriate dimensions. For example, the SiOx filler 430 may be backgrinded match the height of a passive element and/or HBM such as third die 420, or to expose a silicon surface, such as of the Si buffer die 435 and/or an active die for metallization or application of thermal interface material (TIM).

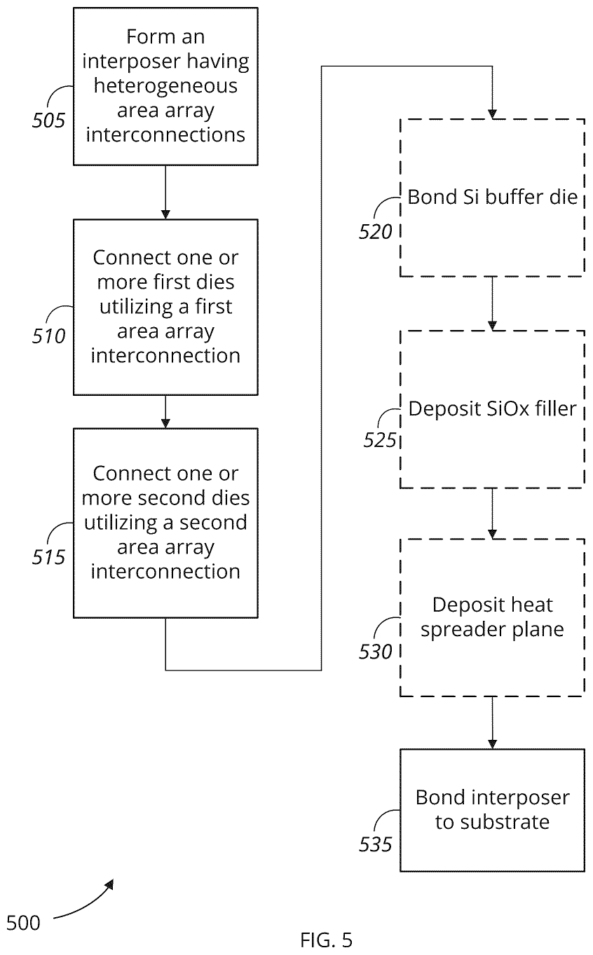

FIG. 5 is a flow diagram of a method 500 of manufacturing a chiplet package with heterogeneous area array interconnections, in accordance with various embodiments. The method 500 includes, at block 505, forming an interposer having heterogeneous area array interconnections. As previously described, the interposer may include a two or more different types (e.g., mixed) of area array interconnections. In some examples, a first type may include area array interconnections utilizing Cu—Cu bonding. A second type may include area array interconnections utilizing solder bumps (e.g., uBump and/or Cu pillar), such as in flip-chip. In further examples, additional types of area array interconnections may be provided via the interposer. In some examples, different area array interconnections may be provided on different sides of the interposer (e.g., a first side for Cu—Cu bonding and a second side for flip-chip/wire bonding). According to various embodiments, the interposer may further be an organic interposer.

The method 500 continues, at block 510, by connecting one or more first dies utilizing a first area array interconnection. As previously described, a first area array interconnection may include one of Cu—Cu bonding or bonding using solder bumps. Accordingly, connecting of the one or more first dies may include, in some examples, flip-chip die bonding of the one or more first dies to the interposer. In other examples, connecting the one or more first dies may include Cu—Cu bonding (e.g., HCB and/or DCB) of the one or more first dies to the interposer.

The method 500 continues, at block 515, by connecting one or more second dies utilizing a second area array interconnection. As previously described, a second area array interconnection may utilize one of Cu—Cu bonding or bonding using solder bumps that is different from the type of area array interconnection utilized by the first area array interconnection. Accordingly, connecting of the one or more second dies may include, in some examples, Cu—Cu bonding (e.g., HCB and/or DCB) of the one or more second dies to the interposer where the one or more first dies are bonded to the interposer using solder bumps to the interposer. In other examples, connecting the one or more second dies may include area array interconnections utilizing solder bumps where the one or more first dies are mounted utilizing Cu—Cu bonded area array interconnections.

The method 500 may further include, at block 520, bonding a silicon buffer die to the one or more first die and/or one or more second die. As previously described, a silicon buffer die may be coupled to the dies of the semiconductor package to provide mechanical rigidity. In some examples, the silicon buffer die may be bonded to the one or more first die and/or one or more second die via SiOx-SiOx bonding. Specifically, at block 525, because the heights of the one or more first die and one or more second die may vary, gaps may filled with a SiOx filler. As previously described, die that are Cu—Cu bonded may have a height (e.g., thickness) that is less than other die that are mounted via solder bumps. Moreover, gaps may exist between Cu—Cu bonded dies. Accordingly, a SiOx filler may be deposited to fill gaps between Cu—Cu bonded dies, and further to match the height of the various dies. Thus, SiOx filler may be deposited in gaps between the various die, such as between the silicon buffer die and one or more first die and/or one or more second die, and between the one or more first dies and one or more second dies.

In some examples, the method 500 continues, at block 530, by depositing a heat spreader plane on the silicon buffer die. As previously described, in some examples, the heat spreader plane may be an MLG plane that is deposited on the silicon buffer die. The heat spreader plane may alternatively include a different type thermally conductive coating/film, or a metal vapor chamber. The silicon buffer die acts as a transition layer to thermally couple the one or more first die and/or one or more second die to the heat spreader.

At block 535, the method 500 continues by bonding the interposer to a substrate (e.g., a package substrate), such as a PCB or other substrate material. In some examples, the interposer may be coupled to the substrate utilizing traditional, wider pitch electrical connections, such as solder balls (e.g., a ball grid array (BGA)).

The techniques and processes described above with respect to various embodiments may be used to manufacture semiconductor packages 100, 200, 300, and 400, and/or components thereof, as described herein.

While some features and aspects have been described with respect to the embodiments, one skilled in the art will recognize that numerous modifications are possible. For example, the methods and processes described herein may be implemented using hardware components, custom integrated circuits (ICs), programmable logic, and/or any combination thereof. Further, while various methods and processes described herein may be described with respect to particular structural and/or functional components for ease of description, methods provided by various embodiments are not limited to any particular structural and/or functional architecture but instead can be implemented in any suitable hardware configuration. Similarly, while some functionality is ascribed to one or more system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. An apparatus comprising:
an interposer comprising one or more area array interconnections, the one or more area array interconnections including a first type of area array interconnection and a second type of area array interconnection;
a first die coupled to the interposer via the first type of area array interconnection; and
a second die coupled to the interposer via the second type of area array interconnection,
wherein the first type of area array interconnection is different from the second type of area array interconnection.

2. The apparatus of claim 1, wherein the interposer comprises an organic interposer.

3. The apparatus of claim 1, wherein the first type of area array interconnection is one of:
a solder bonded interconnection; or
a copper bonded interconnection.

4. The apparatus of claim 3, wherein the solder bonded interconnection includes one of a copper pillar with solder tip or solder micro bump interconnection.

5. The apparatus of claim 3, wherein the copper bonded interconnection includes one of direct copper bonding or hybrid copper bonding of the first die to the interposer.

6. The apparatus of claim 3, wherein the second type of area array interconnection is one of solder bonded or copper bonded, and different from the first type of area array.

7. The apparatus of claim 1, further comprising:
a silicon buffer die coupled to a first surface of the first die and a first surface of the second die.

8. The apparatus of claim 7, wherein the silicon buffer die is coupled to the first and second dies via silicon oxide bonding, wherein a silicon oxide filler is disposed in a gap between at least two of the first die, second die, and silicon buffer die.

9. The apparatus of claim 7, further comprising:
a heat spreader plane coupled to the silicon buffer die, wherein the heat spreader plane is configured to distribute heat within the heat spreader plane.

10. The apparatus of claim 9, wherein the heat spreader plane is a multilayer graphene plane deposited on the silicon buffer die.

11. A semiconductor device comprising:
a circuit board comprising one or more internal layers;
a first semiconductor package coupled to the circuit board, the first semiconductor package including:
a substrate coupled to the circuit board;
an interposer coupled to the circuit board, the interposer comprising one or more area array interconnections, the one or more area array interconnections including a first type of area array interconnection and a second type of area array interconnection;
a first die coupled to the interposer via the first type of area array interconnection; and
a second die coupled to the interposer via the second type of area array interconnection,
wherein the first type of area array interconnection is different from the second type of area array interconnection; and
a second semiconductor package coupled to the circuit board, the second semiconductor package further coupled to the first semiconductor package via at least one of the one or more internal layers of the circuit board.

12. The semiconductor device of claim 11, wherein the interposer comprises an organic interposer.

13. The semiconductor device of claim 11, wherein the first type of area array interconnection is one of:
a solder bonded interconnection; or
a copper bonded interconnection.

14. The semiconductor device of claim 13, wherein the second type of area array interconnection is one of solder bonded or copper bonded, and different from the first type of area array.

15. The semiconductor device of claim 13, wherein the copper bonded interconnection includes one of direct copper bonding or hybrid copper bonding of the first die to the interposer.

16. The semiconductor device of claim 13, wherein the first substrate positioned such that the first side of the first substrate faces the second substrate, wherein second substrate is positioned such that the first side of the second substrate faces the first substrate, and wherein the second side of the second substrate is positioned opposite the first side of the second substrate.

17. The semiconductor device of claim 11, further comprising:
a silicon buffer die coupled to a first surface of the first die and a first surface of the second die.

18. The semiconductor device of claim 11, further comprising:
a heat spreader plane coupled to the silicon buffer die, wherein the heat spreader plane is configured to distribute heat within the heat spreader plane.

19. A method comprising:
forming an interposer comprising one or more area array interconnections, the one or more area array interconnections including a first type of area array interconnection and a second type of area array interconnection;
connecting a first die to the interposer via the first type of area array interconnection;
connecting a second die to the interposer via the second type of area array interconnection, wherein the first type of area array interconnection is different from the second type of area array interconnection; and
bonding the interposer to a package substrate.

20. The method of claim 19, wherein connecting the first die to the interposer via the first type of area array interconnection includes bonding the first die utilizing a plurality of solder bumps, and wherein connecting the second die to the interposer via the second type of area array interconnection includes bonding the second die to the interposer via copper bonding.
